(19) United States
(12) Patent Application Publication
(10) Pub. No.: US 2026/0040850 A1
(43) Pub. Date: Feb. 5, 2026

(54) SEMICONDUCTOR DEVICE HAVING SCULPTED CORNERS AND METHODS FOR MANUFACTURING THE SAME

(71) Applicant: TEXAS INSTRUMENTS INCORPORATED, Dallas, TX (US)

(72) Inventors: Ian Laboriante, Lehi, UT (US); Ximeng Liu, Lehi, UT (US); Matthew Willford, Lehi, UT (US); Zachary Katz, Sandy, UT (US)

(21) Appl. No.: 18/790,893

(22) Filed: Jul. 31, 2024

(51) Int. Cl. H01L 21/306; H01L 21/02; H01L 21/311; H01L 21/762

(52) U.S. Cl. CPC H01L 21/306; H01L 21/02164; H01L 21/31111; H01L 21/76224

(57) ABSTRACT

A method for forming a semiconductor device is disclosed herein. The method includes forming a gradient oxide layer on a surface of a substrate, the etch rate of the gradient oxide layer varies along a thickness of the gradient oxide layer, forming a trench through the gradient oxide layer and into the substrate, the trench at least partially defined by a sidewall of the substrate, wherein the surface and the sidewall are connected to form a corner of the substrate, removing a portion of the gradient oxide layer adjacent the corner, wherein a portion of the surface of the substrate is exposed as a result of removing the portion of the gradient oxide layer, and performing an etching process on the exposed corner of the substrate to form a rounded corner that transitions from the surface of the substrate to the sidewall of the substrate.

### FIELD

The present disclosure generally relates to semiconductor devices, and more particularly, to field effect transistors.

### BACKGROUND

Field effect transistors (FETs), such as metal oxide semiconductor FETs (MOSFETs) and complimentary MOSFETs (CMOS) devices, include transistors formed over a semiconductor substrate. These transistors have active areas where features such as a source, a drain, and a gate are formed. These active areas may include corners that result from the method of manufacture of the transistor. The corners in the active areas may cause undesirable kink effect, gate dielectric breakdown, and/or stresses that may cause junction leakage in FET devices.

### SUMMARY

A method for forming a semiconductor device is disclosed herein. The method includes forming a gradient oxide layer on a surface of a substrate, wherein an etch rate of the gradient oxide layer varies along a thickness of the gradient oxide layer, forming a trench through the gradient oxide layer and into the substrate, the trench at least partially defined by a sidewall of the substrate, wherein the surface and the sidewall are connected to form a corner of the substrate, removing a portion of the gradient oxide layer adjacent the corner, wherein a portion of the surface of the substrate is exposed as a result of removing the portion of the gradient oxide layer, performing an etching process on the exposed corner of the substrate to form a rounded corner that transitions from the surface of the substrate to the sidewall of the substrate, and forming a dielectric layer on the rounded corner of the substrate.

Also disclosed herein is a method for forming a semiconductor device. The method includes forming a gate stack on a surface of a substrate, the gate stack including a gate dielectric layer and a gate electrode layer, forming a dielectric spacer on the gate stack, forming a trench in the substrate adjacent the dielectric spacer, the trench at least partially defined by a sidewall of the substrate, removing, through the trench, a portion of the substrate from under the dielectric spacer to form a rounded corner on the substrate, the rounded corner transitioning from the surface of the substrate to the sidewall of the substrate, and forming a dielectric layer on the rounded corner of the substrate.

Also disclosed herein is a method for forming a semiconductor device. The method includes forming an oxide layer on a surface of a semiconductor substrate, forming a trench through the oxide layer and into the semiconductor substrate, the trench at least partially defined by a sidewall of the semiconductor substrate, performing an etching process on the semiconductor substrate including the sidewall to form a rounded corner on the semiconductor substrate, wherein the rounded corner transitions from the sidewall of the semiconductor substrate to the surface of the semiconductor substrate that is covered by the oxide layer, wherein the etching process includes using an ozonated deionized water or a fluorine-based etchant, and forming a dielectric layer on the rounded corner of the substrate.

The foregoing features and elements may be combined in any combination, without exclusivity, unless expressly indicated herein otherwise. These features and elements as well as the operation of the disclosed examples will become more apparent in light of the following description and accompanying drawings.

### BRIEF DESCRIPTION OF THE DRAWINGS

Reference will now be made to the accompanying drawings, which are not necessarily drawn to scale. While the drawings illustrate various examples employing the principles described herein, the drawings do not limit the scope of the claims.

FIG. 1 illustrates a flowchart for a method of forming a semiconductor device, in accordance with various examples of the present disclosure.

FIGS. 2A, 2B, 2C, 2D1, 2D2, 2E1, 2E2, 2F1, 2F2, 2G, 2H, 211, 212, 2J1, 2J2, 2K1, and 2K2 illustrate cross-section views of a semiconductor device, in accordance with the process of FIG. 1 and the various examples associated therewith.

FIG. 3 illustrates a flowchart for a method of forming a semiconductor device, in accordance with various examples of the present disclosure.

FIGS. 4A, 4B, 4C, 4D, 4E, 4F, 4G, and 4H illustrate cross-section views of a semiconductor device, in accordance with the process of FIG. 3 and the various examples associated therewith.

### DETAILED DESCRIPTION

The following detailed description is presented for purposes of illustration and not of limitation. Benefits, advantages, and/or solutions to problems may be described with reference to various examples. The detailed description makes use of the various examples and refers to the accompanying drawings which illustrate the various examples described herein. The drawings, descriptions, and examples are described in sufficient detail to practice the disclosure. It is understood that connecting lines shown in the various drawings are intended to represent exemplary functional relationships and/or physical couplings between various elements, but that other relationships and/or couplings are possible while remaining within the scope of the present disclosure. It will further be appreciated that the various drawings may not be drawn to scale in order to simplify and clarify the detailed description herein. Furthermore, it is understood that the descriptions and examples contained herein may permit the practice of other examples using logical, chemical, and/or mechanical changes without departing from the spirit and scope of this disclosure. For example, the steps recited in method and process descriptions may be executed in a different order, additional process steps may be added, and/or process steps may be removed while remaining within the scope of the present disclosure.

Any reference to singular items and/or examples includes plural items and/or examples and any reference to more than one item and/or example may include a singular item and/or example. Similarly, references to “a”, “an”, or “the” may include one or more of the referenced items, unless stated otherwise. Any reference to connected, coupled, fixed, attached, or the similar words and/or phrases may include partial, full, temporary, removable, permanent, or the other connection options. Any reference to contact, or similar phrase, may include minimal contact or reduced contact. All ranges used herein may include both the upper and lower values of the ranges, including ratio limits, that are disclosed herein. Stated values may include at least the variation that is expected within the field in which the present disclosure is practiced and as would be understood and accepted to include values that are within 10% of a stated value. Similarly, the use of “approximately”, “about”, “substantially” or other similar term represents an amount that is close to the stated value and that may still achieve the stated, or desired, result and/or perform the stated, or desired, function and may refer to an amount that is within 10% of the stated value.

The accompanying drawings, and detailed description of the drawings, include reference numerals that may be repeated across multiple examples. The repetition of reference numerals is intended simplicity and clarity of description and is not intended to form or dictate a relationship between different examples described herein. The examples and descriptions provided herein are intended to be exemplary and not limiting beyond the scope of the claims. The use of terms such as “on” and “over” may indicate that a first feature is formed directly contacting a second feature or may indicate a relationship of the first feature and the second feature without direct contact between the two, such as additional features being formed between the two.

Spatially relative terms such as, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of discussion herein and are not intended to limit the orientation of the various components, systems, apparatuses, devices, or other features. It is therefore understood and appreciated that the use of the spatially relative terms to practice this disclosure in different orientations remains within the scope of the present disclosure.

Transistors, such as field effect transistors (FETs), include active areas defined by an underlying substrate material layer (e.g. semiconductor substrate). For example, during the manufacture of some FETs, the underlying semiconductor substrate is patterned to define an active area where a gate structure, a source region, and/or a drain region are formed. Active areas have corner regions that transition from an upper surface (e.g. surface upon which the gate is disposed) of the substrate to a sidewall surface (e.g. surface upon which an isolation feature is disposed) of the substrate. These corner regions of the active area may cause undesirable effects during use of the transistor devices including kink effect, gate dielectric breakdown, and/or other stresses that may cause junction leakage in the transistor device.

To address these issues, disclosed herein are methods for manufacturing semiconductor devices that have active areas (e.g. active regions) with rounded corners (e.g. sculpted corners). In various examples, the disclosed methods round the corner region(s) of the underlying substrate to form an active area having rounded corners. A transistor, such as a field effect transistor, disposed over such an active area having rounded corners tends to reduce otherwise the undesirable effects associated active areas not having rounded corners. In various examples contemplated by the present disclosure, rounded corners are formed in the active areas of transistor devices during the manufacture of field effect transistors (FETs) including metal oxide semiconductor FETs (MOSFETs) and complimentary MOSFET (CMOS) devices, among others. Rounding the corners of the active areas, in various examples, tends to provide structural and electrical improvements to FETs. Structurally, the rounded corners tend to mitigate, in various examples, the stress that may lead to gate dielectric breakdown and/or junction leakage. The rounded corners further tend to reduce unwanted accumulation of electric charge at, or near, the rounded corners of active areas in the FETs. In other words, FETs that have sharp corners and/or edges (e.g. non-rounded corners) in active areas tend to have unwanted accumulation of electric charge near these non-rounded corners. Reducing the unwanted accumulation of electric charge through devices having active areas with rounded corners decreases parasitic current leakage and/or capacitances.

The methods disclosed herein, in various examples, include forming a gradient oxide layer on a substrate. In various examples, an etch rate of the gradient oxide layer varies along a thickness of the gradient oxide layer. In various examples, a lower portion of the gradient oxide layer adjacent the substrate has a higher etch rate than an upper portion of the gradient oxide layer. In various examples, an oxygen concentration in the gradient oxide layer varies along the thickness of the gradient oxide layer. In various examples, the lower portion of the gradient oxide layer has a higher concentration of oxygen than the upper portion of the gradient oxide layer. In various examples, the gradient oxide layer may include a plurality of oxide layers. In various examples, each of the plurality of oxide layers may have a different etch rate—e.g., a first oxide layer of the plurality of oxide layers adjacent the substrate having a greater etch rate than other oxide layers of the plurality of oxide layers. In various examples, each of the plurality of layers may have a different concentration of oxygen—e.g., a first oxide layer of the plurality of oxide layers adjacent the substrate having a greater oxygen concentration than other oxide layers of the plurality of oxide layers.

A hard mask is formed on the gradient oxide layer and a trench is formed through the hard mask and the gradient oxide layer. Subsequently, the gradient oxide layer, in various examples, may be pulled back, or partially etched, under the hard mask layer with little to no etching of the hard mask layer or the substrate. As a result of pulling back the gradient oxide layer, a corner of the substrate may be exposed. In various examples, a lower portion of the gradient oxide layer adjacent the substrate may be etched at a higher rate than an upper portion of the gradient oxide layer adjacent the hard mask. The exposed corner of the substrate may be rounded (e.g. sculpted) utilizing one or more etch process. In various examples, the etching process for corner rounding may include a wet chemical etch, a dry chemical etch such as a gas-phase etch (e.g., a vapor etch), or combinations thereof. In various examples, the etching process may provide a vertically asymmetric etching profile (or a vertically gradient etching profile)—e.g., from top to bottom on vertical sidewall of the substrate.

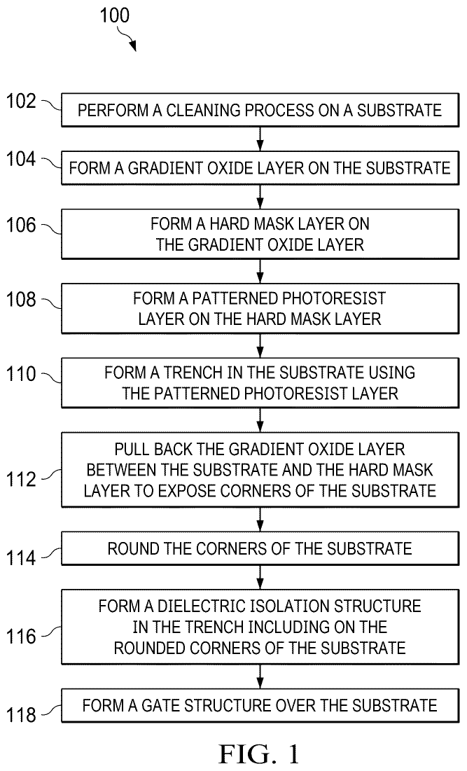

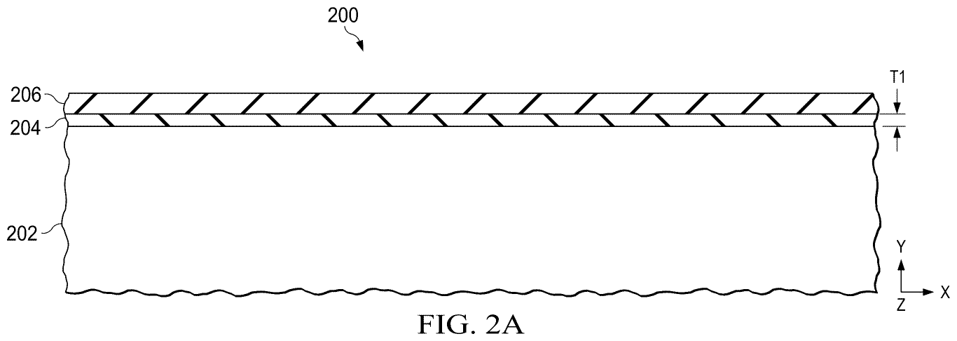

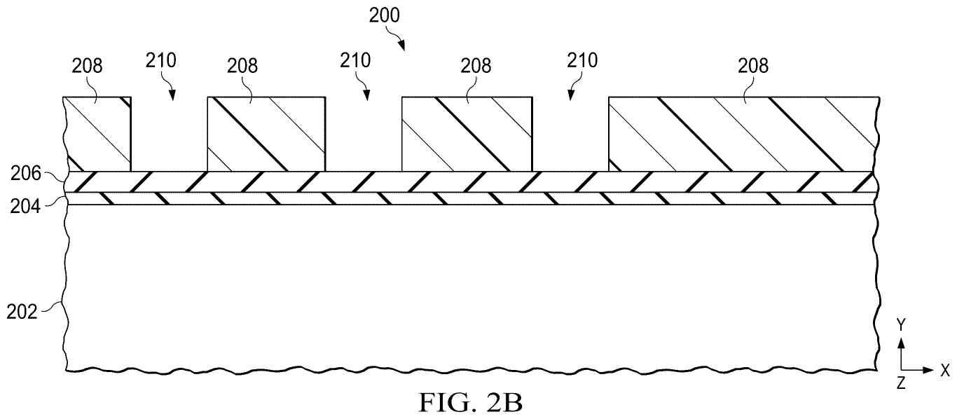

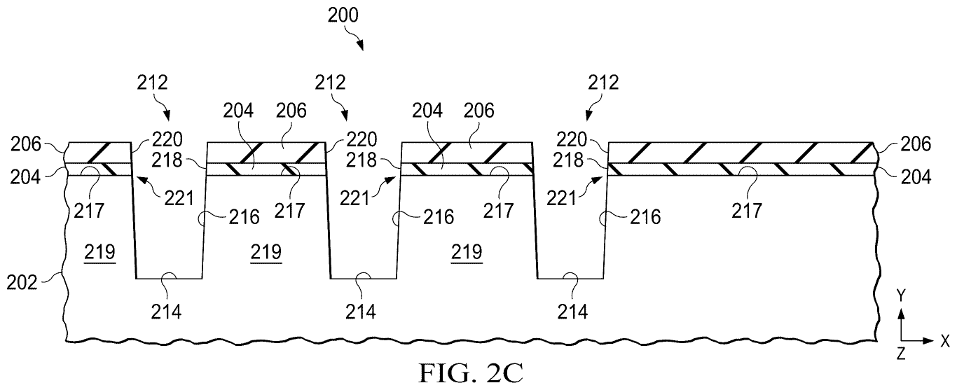

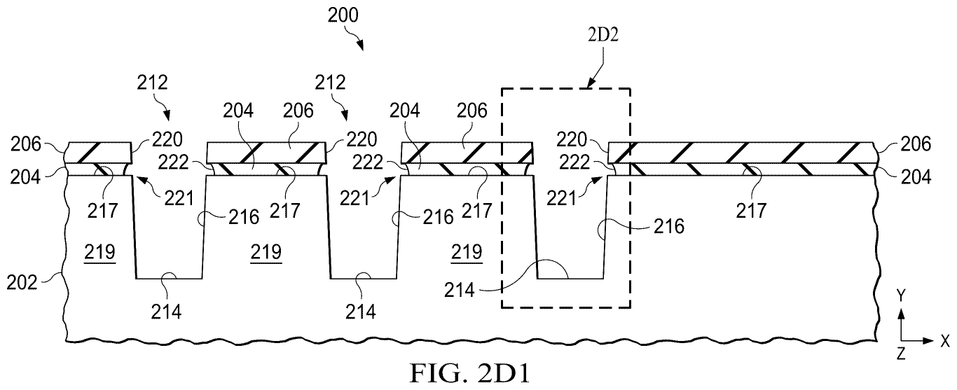

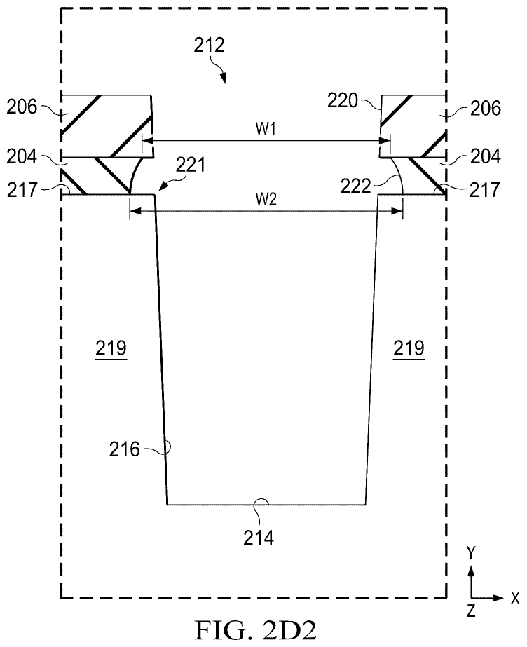

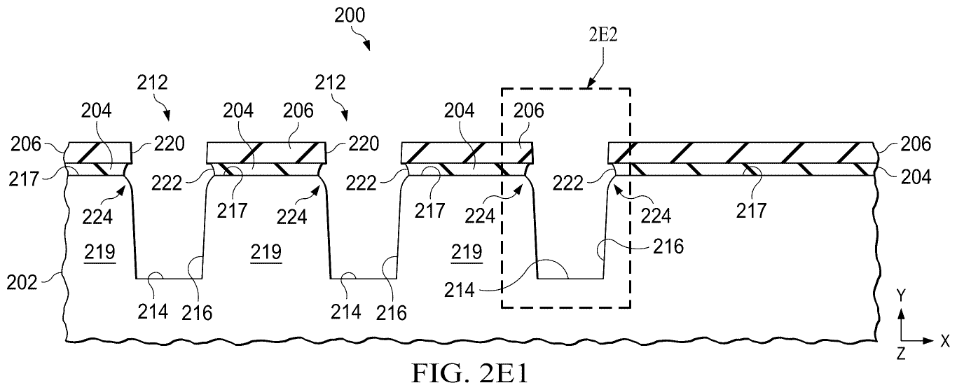

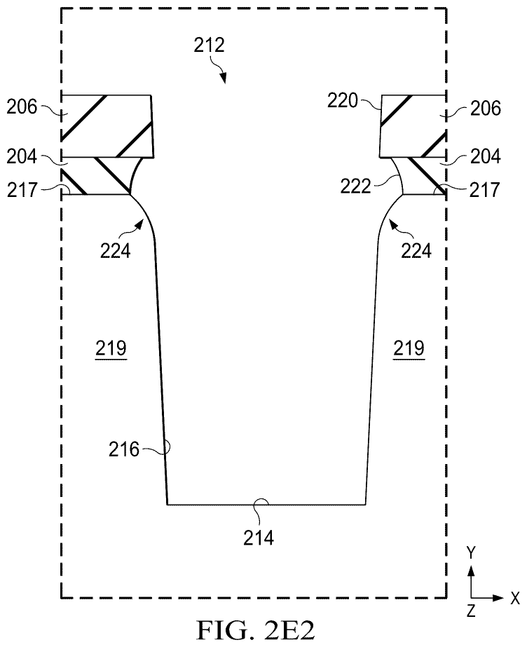

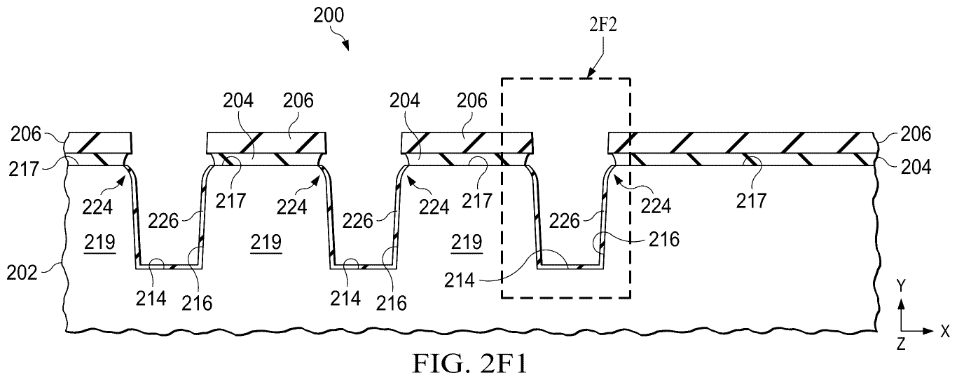

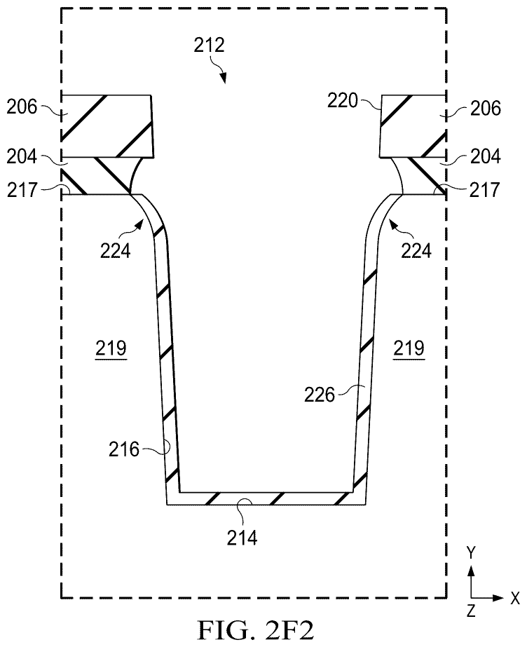

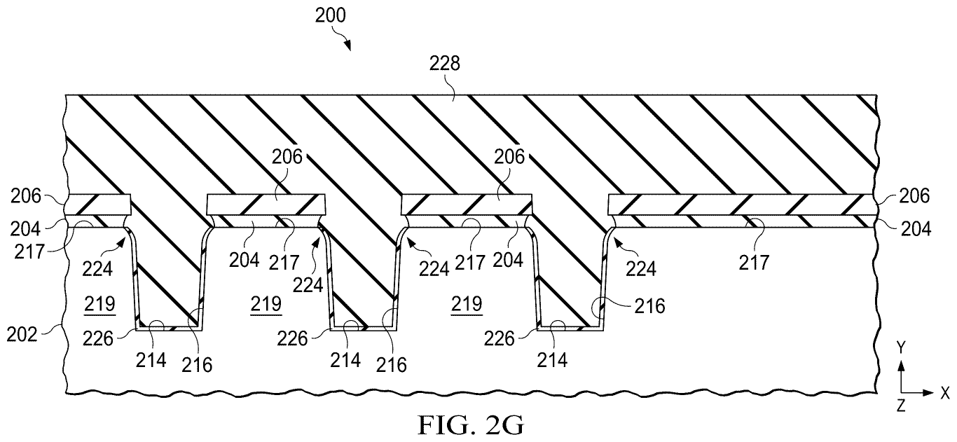

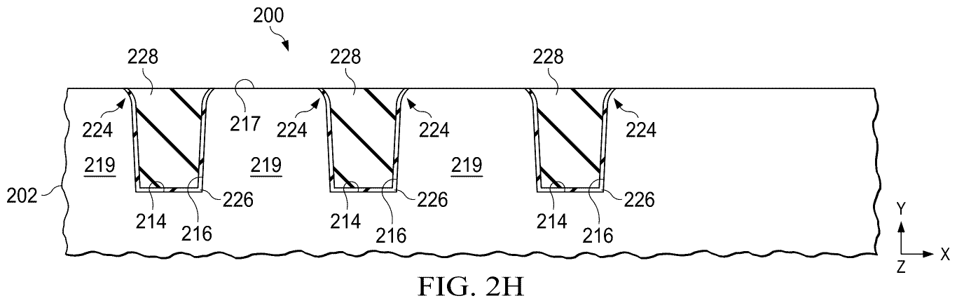

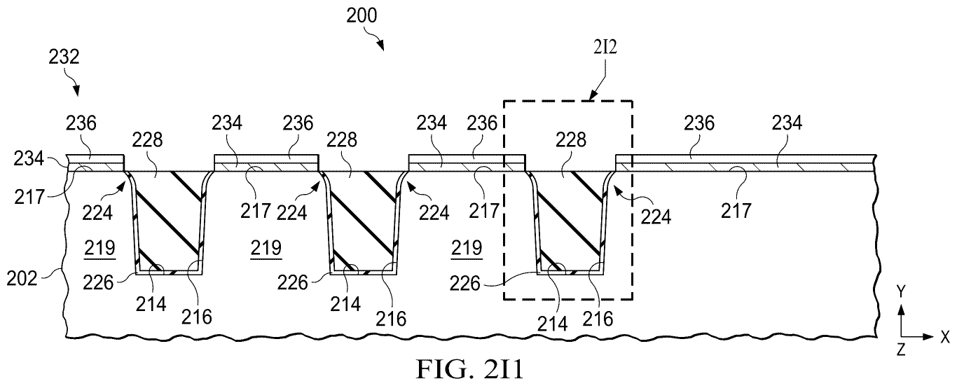

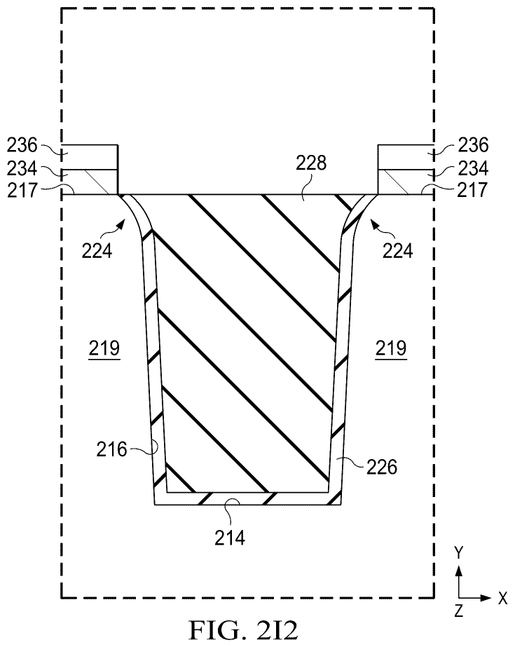

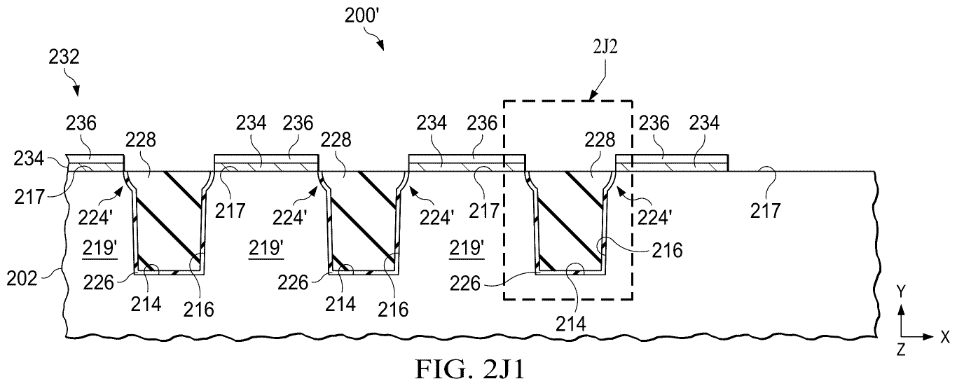

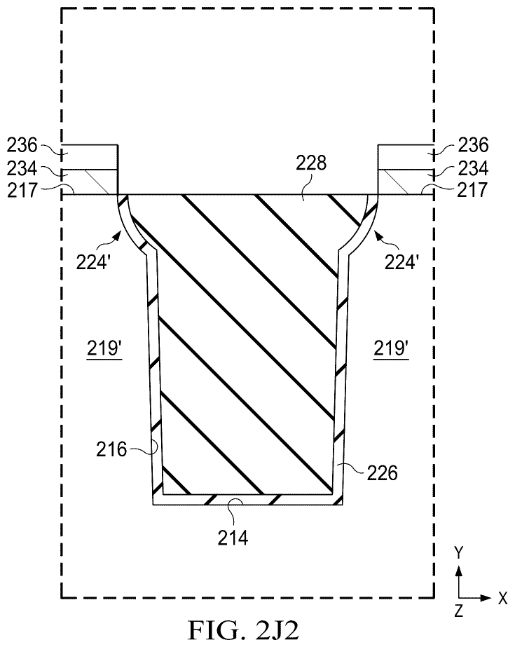

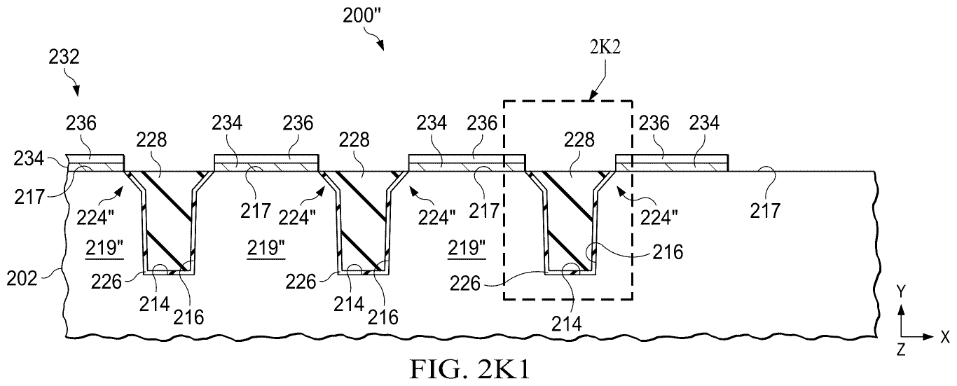

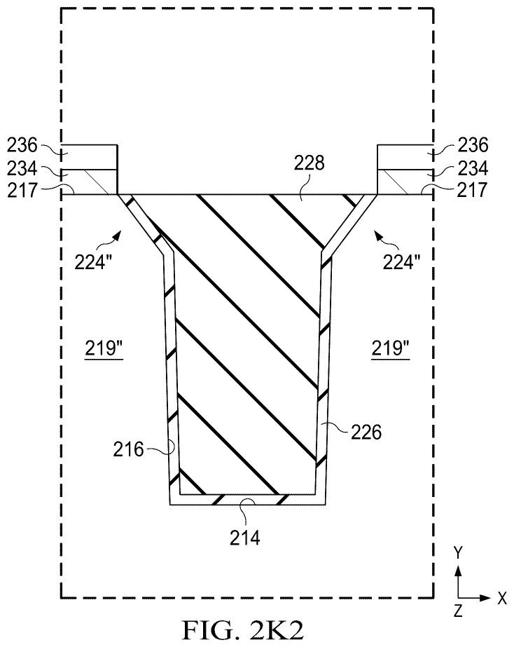

Referring now to FIG. 1, a flow diagram of a method 100 for forming a semiconductor device having an active area with sculpted corners, in accordance with various examples of the present disclosure. In various examples, method 100 may be used to form rounded corners (e.g. sculpted corners) in active areas of a substrate for semiconductor devices such as a field effect transistor (FET), a metal oxide semiconductor FET (MOSFET), a complimentary MOSFET (CMOS), a laterally diffused MOSFET (LDMOS), among others. Additional processes can be provided before, during, and after method 100. As described below, method 100 is described with reference to FIGS. 2A-2K2.

In that regard, FIGS. 2A-2K2 are diagrammatic cross-sectional views of a device 200 at various stages of fabrication (such as those associated with method 100 of FIG. 1), according to various aspects of the present disclosure. In various examples, device 200 may be a semiconductor device such as a field effect transistor (FET), a metal oxide semiconductor FET (MOSFET), a complimentary MOSFET (CMOS), a laterally diffused MOSFET (LDMOS), among others. Additional features can be added to device 200, and some features described below can be replaced, modified, or eliminated in other examples of device 200.

At steps 102, 104, and 106 of FIG. 1, a cleaning process on a substrate is performed, a gradient oxide layer is formed on the substrate, and a hard mask layer (e.g. a nitride layer) is formed on the gradient oxide layer. As shown in FIG. 2A, device 200 includes a substrate 202, a gradient oxide layer 204 formed on substrate 202, and a nitride layer 206 formed on gradient oxide layer 204. Substrate 202, in various examples, may include one or more layers of silicon (Si), silicon germanium (SiGe), or combinations thereof. In various examples, one or more layers of substrate 202 may include an n-type dopant, a p-type dopant, or combinations thereof. In various examples, substrate 202 may be epitaxially grown. In some examples, substrate 202 may include an insulating layer, such that substrate 202 may be considered a silicon-on-insulator (SOI) substrate. As described below, substrate 202 is patterned to form active areas upon which a gate structure of a transistor is formed.

Gradient oxide layer 204 may be formed on substrate 202. In various examples, gradient oxide layer 204 may be formed by a diffusion process, a chemical vapor deposition process (CVD), an atomic layer deposition process (ALD), or a combination thereof. In various examples, gradient oxide layer 204 may include silicon oxide, silicon oxynitride and/or a combination thereof. The use of the term silicon oxide throughout this disclosure includes materials such as silicon monoxide (SiO) and/or silicon dioxide (SiO₂) and/or a non-stoichiometric mixture of the two.

In various examples, gradient oxide layer 204 may be formed as a single oxide layer. In various examples, gradient oxide layer 204 may include a plurality of oxide layers. In various examples, the plurality of layers forming gradient oxide layer 204 may be formed individually using one or more distinct processes. As described below, regardless of whether gradient oxide layer 204 is formed of a single oxide layer or more than one oxide layer (e.g. plurality of oxide layers) gradient oxide layer 204 may have a concentration gradient of oxygen that varies along the thickness of the gradient oxide layer.

As shown, gradient oxide layer 204 has a thickness t1. In various examples, thickness t1 may be about 100 Å to about 250 Å, and more specifically, about 125 Å to about 200 Å. In other examples, thickness t1 may be less than about 100 Å. Gradient oxide layer 204 may have, in various examples, a concentration of oxygen that varies along thickness t1 of gradient oxide layer 204. The concentration of oxygen may increase in a first direction (e.g., the negative y-direction) toward substrate 202. That is, the oxygen concentration in gradient oxide layer 204 increases along thickness t1 in the direction of substrate 202. As such, a lower portion of gradient oxide layer 204 that is adjacent substrate 202, in various examples, has a higher concentration of oxygen than an upper portion of gradient oxide layer 204 that is positioned further away from substrate 202.

In various examples, when gradient oxide layer 204 is a single oxide layer the lower portion of the single oxide layer that is adjacent substrate 202 has a higher concentration of oxygen than an upper portion of the single oxide layer that is positioned further away from substrate 202. In various examples, when gradient oxide layer 204 includes a plurality of oxide layers each layer of the plurality of oxide layers has a different concentration of oxygen than the other layers of the plurality of oxide layers such that the concentration of oxygen increases across gradient oxide layer 204 in the first direction (e.g., the negative y-direction) toward substrate 202. In various examples, when gradient oxide layer 204 includes a plurality of oxide layers, the lower portion (e.g. adjacent substrate 202) of gradient oxide layer 204 may be one or more lower oxide layers of the plurality of oxide layers (having higher concentrations of oxygen) and the upper portion (e.g. adjacent nitride layer 206) of gradient oxide layer 204 may be one or more upper oxide layers of the plurality of oxide layers (having lower concentrations of oxygen). In various example, the one or more lower oxide layers of the plurality of oxide layers may have successive higher concentrations of oxygen and the one or more upper oxide layers of the plurality of oxide layers may have successive lower concentrations of oxygen. That is, the concentration of oxygen increases in each of the one or more oxide layers of the lower portion in the direction towards substrate 202 (e.g., the negative y-direction) and the concentration of oxygen decreases in each of the one more oxide layers of the upper portion in the direction away from substrate 202 (e.g., the positive y-direction).

The concentration of oxygen in gradient oxide layer 204 may be varied by changing process parameters associated with the formation of gradient oxide layer 204. As described above, a diffusion process, a chemical vapor deposition process (CVD), an atomic layer deposition process (ALD), or a combination thereof may be used to form gradient oxide layer 204. As such, for example, process parameters such as temperature, oxygen, hydrogen, and/or carbon concentration ratios, deposition rates, duration, and/or pressure, among other parameters, may be modified to alter the concentration gradient of oxygen along the thickness t1 of gradient oxide layer 204. For example, the portions of gradient oxide layer 204 having relatively higher etch rates (e.g., having higher concentrations of oxygen, the lower layer(s) of gradient oxide layer 204) may be formed at lower temperatures, higher deposition rates, and/or higher concentration of hydrogen and/or carbon than the portions of gradient oxide layer 204 having lower etch rates (e.g., having lower concentrations of oxygen, the upper layer(s) of gradient oxide layer 204). The concentration gradient of oxygen within gradient oxide layer 204 may be design dependent and may be more or less, depending on the design for a specific application, in various examples. Additionally, thickness t1 of gradient oxide layer 204 may be design dependent and may be greater or smaller depending on the design for a specific application, in various examples.

In various examples, gradient oxide layer 204 may have an etch rate that varies along thickness t1 of gradient oxide layer 204. The etch rate may increase in the first direction (e.g., the negative y-direction) toward substrate 202. That is, the etch rate in gradient oxide layer 204 increases along thickness t1 in the direction of substrate 202. As such, a lower portion of gradient oxide layer 204 that is adjacent substrate 202, in various examples, has a higher etch rate than an upper portion of gradient oxide layer 204 that is positioned further away from substrate 202.

The etch rate within gradient oxide layer 204 may be design dependent and may be more or less, depending on the design for a specific application, in various examples. In various examples and in addition to the concentration of oxygen (or in lieu of), the etch rate may depend on a density through thickness t1 of gradient oxide layer 204, bonding strengths of the chemicals used in gradient oxide layer 204, and/or precursor elements to various processes that may be found in gradient oxide layer 204, among others.

In various examples, when gradient oxide layer 204 is a single oxide layer the lower portion of the single oxide layer that is adjacent substrate 202 has a higher etch rate than an upper portion of the single oxide layer that is positioned further away from substrate 202. In various examples, when gradient oxide layer 204 includes a plurality of oxide layers each layer of the plurality of oxide layers has a different etch rate than the other layers of the plurality of oxide layers such that the etch rate increases across gradient oxide layer 204 in the first direction (e.g., the negative y-direction) toward substrate 202. In various examples, when gradient oxide layer 204 includes a plurality of oxide layers, the lower portion (e.g. adjacent substrate 202) of gradient oxide layer 204 may be one or more lower oxide layers of the plurality of oxide layers (having a higher etch rate) and the upper portion (e.g. adjacent nitride layer 206) of gradient oxide layer 204 may be one or more upper oxide layers of the plurality of oxide layers (having a lower etch rate). In various example, the one or more lower oxide layers of the plurality of oxide layers may have successive higher etch rates and the one or more upper oxide layers of the plurality of oxide layers may have successive lower etch rates. That is, the etch rate increases in each of the one or more oxide layers of the lower portion in the direction towards substrate 202 (e.g., the negative y-direction) and the etch rate decreases in each of the one more oxide layers of the upper portion in the direction away from substrate 202 (e.g., the positive y-direction).

The etch rate in gradient oxide layer 204 may be varied by changing process parameters associated with the formation of gradient oxide layer 204. As described above, a diffusion process, a chemical vapor deposition process (CVD), an atomic layer deposition process (ALD), or a combination thereof may be used to form gradient oxide layer 204. As such, for example, process parameters such as temperature, chemical mixture ratios, duration and/or pressure, among other parameters, may be modified to alter the etch rate along the thickness t1 of gradient oxide layer 204. As described above, in various examples and in addition to the concentration of oxygen (or in lieu of), the etch rate may depend on a density through thickness t1 of gradient oxide layer 204, bonding strengths of the chemicals used in gradient oxide layer 204, and/or precursor elements to various processes that may be found in gradient oxide layer 204, among others.

Nitride layer 206 (e.g. hard mask layer) may be formed on gradient oxide layer 204. Nitride layer 206 may formed on the upper portion, or upper layer, of gradient oxide layer 204. Nitride layer 206 may act as a hard mask and/or a stop layer for later processes. In various examples, nitride layer 206 may include silicon nitride and/or silicon oxynitride. In various examples, nitride layer 206 may be formed by a low-pressure chemical vapor deposition (LPCVD) process using dichlorosilane and ammonia. Alternatively, nitride layer 206 may be formed by decomposition of bis(tertiary-butyl-amino) silane (BTBAS). Other processes to form nitride layer 206 are possible.

At step 108 of FIG. 1, a patterned photoresist layer is formed on the hard mask layer. As shown in FIG. 2B, a patterned photoresist layer 208 is formed on nitride layer 206 having openings 210 exposing nitride layer 206. Photoresist layer 208 may be a positive photoresist material or a negative photoresist material. In various examples, photoresist layer 208 may be formed during a single process or during multiple processes. In various examples, one or more lithography processes may be performed to pattern photoresist layer 208. In various examples, one or more developing processes may be performed to form openings 210.

At step 110 of FIG. 1, a trench is formed in the substrate using the patterned photoresist layer. As shown in FIG. 2C, trenches 212 are formed through nitride layer 206, gradient oxide layer 204, and into substrate 202. Trenches 212 expose a bottom surface 214 and a sidewall 216 of substrate 202 while a top surface 217 (e.g. upper surface) of substrate 202 remains covered by gradient oxide layer 204. Trenches 212 further expose a sidewall 218 of gradient oxide layer 204 and a sidewall 220 of nitride layer 206. In various examples, one or more etching processes may be performed to remove a portion of nitride layer 206, a portion of gradient oxide layer 204, and a portion of substrate 202 to form trenches 212. In various examples, the one or more etching processes may include a wet etch process, a dry etch process, or a combination thereof. In various examples, particles and/or etch polymers may remain on device 200 after performing the one or more etching processes. After the etching to form trenches 212 is performed, patterned photoresist layer 208 is removed such as by a plasma ashing process.

In various examples, after forming trenches 212, sidewall 216, sidewall 218, and sidewall 220 may be aligned with each other. In other words, an outer portion of trenches 212 may be defined by sidewall 216, sidewall 218, and sidewall 220 extending along the same plane. In various examples, sidewall 216, sidewall 218, and sidewall 220 may be substantially vertical (e.g., along the y-axis, such as substantially perpendicular to the x-axis). In various examples, sidewall 216, sidewall 218, and sidewall 220 may be angled outward (e.g., angled away from the y-axis, such as extending at either an acute angle or an obtuse angle with respect to the x-axis) from a center of trenches 212.

As described above, the patterning of substrate 202 delineates portions of substrate 202 that define active areas 219. Active areas 219 are where active parts of the transistor are formed, such as a gate structure, a source region, and/or drain region. As shown, the portions of substrate 202 defining active areas 219 have corners 221 that are covered in part by gradient oxide layer 204. The non-sculpted (e.g. non-rounded) nature of corners 221 (e.g. sharp corners) tend to cause undesirable effects during use of the transistor device such as kink effect, gate dielectric breakdown, and/or other stresses that may cause junction leakage in the transistor device. To address these issues, as described below, the disclosed process sculpts (e.g. rounds) corners 221 of active areas 219 in subsequent process steps. By doing so, the undesirable effects of kink effect, gate dielectric breakdown, and/or other stresses that may cause junction leakage in the transistor are prevented and/or mitigated.

At step 112 of FIG. 1, the gradient oxide layer is pulled back (e.g. partially removed or etched) between the substrate and the hard mask layer to expose corners 221 of the substrate. As shown in FIGS. 2D1 and 2D2, a portion of gradient oxide layer 204 between substrate 202 and nitride layer 206 is pulled back, or etched, to expose a portion of top surface 217 of substrate 202 and a sidewall 222 of gradient oxide layer 204. A cross-sectional profile of corners 221 of substrate 202 (e.g. active areas 219) may be defined by the intersection of sidewall 216 and the exposed portion of top surface 217. FIG. 2D2 is an enlarged view of a single trench 212 of FIG. 2D1 to clarify the details of the pull back, or etching, process.

The pull back of gradient oxide layer 204 may be performed by one or more etching processes. In various examples, the one or more etching processes may include a wet etch, a dry etch such as a gas-phase etch (e.g., a vapor etch), or a combination thereof. The one or more etching processes, in various examples, may remove the particles and/or etch polymers that are present after the processes of step 110 and pull back gradient oxide layer 204. The one or more etching processes may remove more of the exposed gradient oxide layer 204 adjacent substrate 202 than that adjacent nitride layer 206. This is due to the difference in etch rate (e.g. due to oxygen concentration) through thickness t1 of gradient oxide layer 204 described above. The etch rate of gradient oxide layer 204 may increase as the oxygen concentration in gradient oxide layer 204 increases. Because the etch rate (e.g. oxygen concentration) increases along thickness t1 in the direction of substrate 202, the lower portion of gradient oxide layer 204 closer to substrate 202 is removed at a higher rate than the upper portion of gradient oxide layer 204 that is positioned closer to nitride layer 206. Accordingly, more of the lower portion of gradient oxide layer 204 is etched closer to substrate 202 than the upper portion of gradient oxide layer 204 closer to nitride layer 206. As shown in FIGS. 2D1 and 2D2, the upper portion of sidewall 222 of gradient oxide layer 204 remains close to sidewall 220 of nitride layer 206 while the lower portion of sidewall 222 is pulled away from sidewall 216 of substrate 202 exposing a portion of top surface 217 of substrate 202. In various examples, the upper portion of sidewall 222 may be etched, or pulled back, further from sidewall 220 of nitride layer 206.

As shown in FIG. 2D2, because more of gradient oxide layer 204 adjacent substrate 202 has been removed portions of top surface 217 of substrate 202 as well as corners 221 of substrate 202 are exposed. That is, gradient oxide layer 204 has a sidewall 222 that is tapered in the first direction (e.g., the negative y-direction), allowing the underlying corners 221 of the various active areas 219 to be exposed. As shown, trench 212 has a first width w1 and a second width w2 that extends substantially horizontally across trench 212. First width w1 extends from the upper portion of gradient oxide layer 204 on a first side of trench 212 to the upper portion of gradient oxide layer 204 on a second side of trench 212 opposing the first side. Second width w2 extends from the lower portion of gradient oxide layer 204 on the first side of trench 212 to the lower portion of gradient oxide layer 204 on the second side of trench 212. Second width w2 is greater than first width w1 because of the taper of sidewall 222 in the first direction. The taper of sidewall 222 may alternatively be referred to as a retrograde profile or a reverse taper.

At step 114 of FIG. 1, the corners of the substrate are rounded. As shown in FIGS. 2E1 and 2E2, a cross-sectional profile of sculpted corners 224 (e.g. rounded corners) are formed by etching the exposed corners 221 of active areas 219 of substrate 202. As described above, the exposed corners 221 of the active areas 219 are defined by the intersection of sidewall 216 and the exposed portion of top surface 217 of substrate 202. In various examples, one or more etching processes may be performed to form sculpted corners 224. As shown, sculpted corners 224 transition from remaining portions of top surface 217 to remaining portions of sidewall 216 of substrate 202. In various examples, sculpted corners 224 may be linear, convex, or concave, among others. As shown in FIGS. 2E1 and 2E2, sculpted corners 224 are convex corners (e.g. rounded convex corners).

In various examples, the one or more etching processes to form sculpted corners 224 may be a wet chemical etching process, a gas-phase etching process, or a combination thereof. In various examples, the one or more etching process may include a first etching process and a second etching process. In various examples, a first etching process using a fluorine-based etchant may be performed to remove native oxide and/or other oxide remnants from substrate 202, including sidewall 216 and top surface 217 of substrate 202. In some examples, the fluorine-based etchant may include hydrogen fluoride (HF), hydrofluoric acid, or ammonium fluoride (NH₄F) and HF. In various examples, the fluorine-based etchant may be mixed with deionized (DI) water at a ratio of about 10:1 to about 500:1. In various examples, mixing may be performed at a temperature of about 20° C. to about 55° C. Thereafter, a second etching process using ozonated deionized water (DIO₃) may be performed for oxidative etching. An ozone (O₃) concentration in the DIO₃, in various examples, may be about 1 ppm to about 100 ppm. In various examples, the DIO₃ may be used at a temperature of about 20° C. to about 40° C. The second etching process using DIO₃ may asymmetrically etch sidewall 216 of substrate 202 and the exposed portion of top surface 217 of substrate 202. In various examples, the wet chemical etching process may etch, or remove, substrate 202 asymmetrically from an upper portion (e.g., in the positive y-direction) to a lower portion (e.g., in the negative y-direction). In other words, the asymmetric etch may remove more material from substrate 202 at the upper portion than at the lower portion creating sculpted corners 224. The asymmetric etch may be a result of a concentration gradient and decay of the dissolved DIO₃ that is used—e.g., as the strength of the oxidative etching decreases toward the lower portion of the trench 212. In various examples, a vertical depth of the etch may be controlled by altering the process, or exposure, times of the wet chemical etch process. In various examples, the second etching process including the DIO₃ may be performed before the first etching process including the fluorine-based etchant. The first etching process and the second etching process may be repeated one or more times depending on a target critical dimension bias.

In various alternative examples, the one or more etching processes to form sculpted corners 224 may include a vapor etch process, also referred to as gas-phase chemical etch or a chemical dry etch. In these various alternative examples, the vapor etch process may have a high selectivity of Si over an oxide material and/or nitride material. For example, when substrate 202 is formed of silicon, gradient oxide layer 204 is formed of an oxide material (e.g. silicon oxide and/or silicon oxynitride), and nitride layer 206 is formed of a nitride material (e.g. silicon nitride and/or silicon oxynitride), the vapor etch process may etch more of substrate 202 than either of gradient oxide layer 204 or nitride layer 206 due to the high etch selectivity for silicon. As such, corners 221 of the active areas 219 are rounded to form sculpted corners 224. The etching process may be modified to affect the degree to which corners 221 of active areas 219 are sculpted (e.g. rounded). For example, the etch may be tuned by modifying the etchant used, the concentration of the etchant, the temperature of the chamber used, the pressure of the chamber, and/or the duration of the etch, among others.

In various examples, the vapor etch process may be an isotropic vapor etch process. The vapor etch process may include nitrogen trifluoride (NF₃), ammonia (NH₃), hydrofluorocarbons (CₓH_{y}Fₓ), sulfur hexafluoride (SF₆), boron trifluoride (BF₃), or other fluorine-based etchants. In various examples, one or more carrier gases may be used during the vapor etch process. For example, the one or more carrier gases may be one or more noble gases including argon (Ar), helium (He), neon (Ne), and/or nitrogen (N₂), among others. In various examples, the high etch selectivity provides precise control for removal of substrate 202 (e.g. silicon substrate) with a gradient etch profile from top to bottom tunability—e.g., removing more Si near the top surface of the substrate than near the bottom of the trench. In various examples, the vapor etch process may be performed at a pressure of about 0.001 Torr to about 10 Torr. In various examples, the etchants may be about 10% to about 100% relative to the one or more carrier gases used. In various examples, the temperature of the vapor etch process may be about 10° C. to about 250° C.

At step 116, a dielectric isolation structure is formed in the trench including on the rounded corners of the substrate. As shown in FIGS. 2F1, 2F2, 2G, and 2H an oxide liner 226 is formed on device 200 including in trenches 212 and on sculpted corners 224 of active areas 219. Subsequently, a dielectric material 228 is then formed on oxide liner 226, gradient oxide layer 204, and nitride layer 206. As shown in FIGS. 2F1 and 2F2, oxide liner 226 may be formed on substrate 202 including on bottom surface 214, sidewall 216, and sculpted corners 224. In particular, oxide liner 226 may conform to the sculpted corners 224 such that the sculpted nature (e.g. roundness) of the corner is continued in the cross-sectional profile of the oxide liner 226. In various examples, oxide liner 226 may be formed by a diffusion process, a chemical vapor deposition (CVD) process, a physical vapor deposition (VPD) process, a thermal oxidation process, or a combination thereof. In various examples, oxide liner 226 may include silicon oxide, silicon oxynitride and/or a combination thereof. In some examples, forming oxide liner 226 may further round sculpted corners 224.

As shown in FIG. 2G, dielectric material 228 is formed on device 200 including on oxide liner 226 in trenches 212, gradient oxide layer 204, and nitride layer 206. Dielectric material 228 may be formed of one or more layers of dielectric material. In various examples, dielectric material 228 may include a silicon oxide, such as silicon monoxide and/or silicon dioxide, or a nitrogen oxide, such as silicon nitride and/or silicon oxynitride.

As shown in FIG. 2H, a planarization process is performed on device 200. The planarization process removes a portion of dielectric material 228. In various examples, the planarization process may be a chemical mechanical polishing (CMP) process or other similar process. Subsequently, nitride layer 206 and gradient oxide layer 204 are removed to expose substrate 202 including the upper surface of active areas 219.

At step 118 of FIG. 1, a gate structure is formed on the substrate. As shown in FIGS. 211 and 212 a gate structure 232 (e.g. gate stack) is formed. A gate dielectric layer 234 is formed on substrate 202 and a gate electrode layer 236 is formed on gate dielectric layer 234. An etching process may then be performed to etch gate dielectric layer 234 and gate electrode layer 236 to form gate structure 232. Gate dielectric layer 234, in various examples, may include any gate dielectric material including a high-k dielectric material. For example, gate dielectric layer 234 many include dielectric materials such as silicon oxide, hafnium oxide, and/or zirconium oxide. Gate dielectric layer 234 may be formed on substrate 202 and adjacent dielectric material 228 and sculpted corners 224 of substrate 202. Gate electrode layer 236 may be formed on gate dielectric layer 234. Gate electrode layer 236 may, in various examples, include polycrystalline silicon, also referred to as polysilicon, titanium nitride, and/or other metals and metal alloys. In various examples, the etching process may include one or more etching processes. In various examples, the one or more etching processes may include a dry chemical etch process, a wet chemical etch process, or a combination thereof.

Additional processing steps may be performed on device 200. The additional processing steps may, in various examples, continue sculpting sculpted corners 224 of substrate 202 as materials and/or layers are removed, added, and removed from sculpted corners 224. Additional processing steps may include forming source regions, drain regions, and/or body regions. Additional processing steps may further include forming an interlayer dielectric layer over device 200, and forming source contacts, drain contacts, and/or gate contacts through the interlayer dielectric layer.

As previously described above in FIGS. 2E1 and 2E2, sculpted corners 224 of active areas 219 may have different profiles including linear, convex, or concave, among others. The different cross-sectional profiles of sculpted corners 224 may be achieved by adjusting the parameters of the etching processes described above. In various examples, the adjusted parameters may include a type of etchant, a concentration of the etchant, a temperature of the etching process, a timing of the etching process, and/or the pressure of the etching process, among other parameters. Sculpted corners 224 having a convex profile are described above in FIGS. 2E1 and 2E2. Sculpted corners 224′ having a concave profile are illustrated in FIGS. 2J1 and 2J2 and sculpted corners 224″ having a more linear profile are illustrated in FIGS. 2K1 and 2K2.

Referring now to FIGS. 2J1 and 2J2, a device 200′ including active areas 219′ having sculpted corners 224′ is illustrated, in accordance with various examples of the present disclosure. Device 200′ is similar to device 200 described above in FIGS. 2A-212 in that device 200′ includes substrate 202, gate structure 232, gate dielectric layer 234, and gate electrode layer 236. Device 200′ further includes active areas 219′ having sculpted corners 224′, which are different than sculpted corners 224. As stated above, sculpted corners 224′ of active areas 219′ have a concave profile. The concave profile of sculpted corners 224′ is understood to be the opposite of the convex profile of sculpted corners 224 in that a curve of sculpted corners 224′ is in a first direction while a curve of sculpted corners 224 curves is in an opposing second direction.

Referring now to FIGS. 2K1 and 2K2, a device 200″ including active areas 219″ having sculpted corners 224″ is illustrated, in accordance with various examples of the present disclosure. Device 200″ is similar to device 200 described above in FIGS. 2A-212 in that device 200″ includes substrate 202, gate structure 232, gate dielectric layer 234, and gate electrode layer 236. Device 200″ further includes active areas 219″ having sculpted corners 224″, which are different than sculpted corners 224. As stated above, corners 224″ of active areas 219″ have a linear profile. In various examples, sculpted corners 224′ have a generally straight profile—an edge that extends substantially along the same plane from top surface 217 to sidewall 216 of substrate 202. Here, generally straight is understood to mean that sculpted corners 224′ do not have a noticeable curve, either concave or convex, in any direction. Deviation from a true straight line, as is the case during manufacture of semiconductor devices that includes statistical variations, is within the scope of generally straight as described herein.

As described above, transistors formed over active areas having non-sculpted corners (e.g., sharp corners) may have undesirable effects during use of the transistor devices including kink effect, gate dielectric breakdown, and/or other stresses that may cause junction leakage in the transistor device. To address these issues, disclosed herein are methods for manufacturing semiconductor devices having active areas with sculpted corners. A transistor, such as a field effect transistor (FET), disposed over such an active area having sculpted corners tends to reduce the otherwise undesirable effects associated active areas not having sculpted corners.

Specifically, for example, each of the sculpted corners 224, 224′ and 224″ provide improvements to field effect transistors structurally and electrically. Structurally, sculpted corners (e.g. 224, 224′, and 224″) tend to mitigate, in various examples, the stress that may lead to gate dielectric breakdown and/or junction leakage. For example, sculpted corners 224, 224′, and 224″ mitigate these effects by reducing the sharpness of the corners (e.g. corner 221) of active areas 219, 219′, and 219″. The reduced sharpness of sculpted corners 224, 224′, and 224″ tend to reduce structural stress that may lead to gate dielectric breakdown and/or junction leakage. Electrically, sculpted corners 224, 224′, and 224″ also provide additional space for dielectric material (e.g. dielectric material 228 and/or oxide liner 226) which in turns provides more isolation of active areas 219, 219′, and 219″ from gate structure 232 and/or source/drain regions. Sculpted corners 224, 224′, and 224″ further tend to reduce unwanted accumulation of electric charge at, or near, the sculpted corners of active areas in the FETs. In other words, FETs that have sharp corners and/or edges (e.g. non-sculpted corners such as corner 221) in active areas tend to have unwanted accumulation of electric charge near these non-rounded corners. Reducing the unwanted accumulation of electric charge through devices having active areas with sculpted corners 224, 224′, and 224″ tends to reduce parasitic current leakage and/or capacitances.

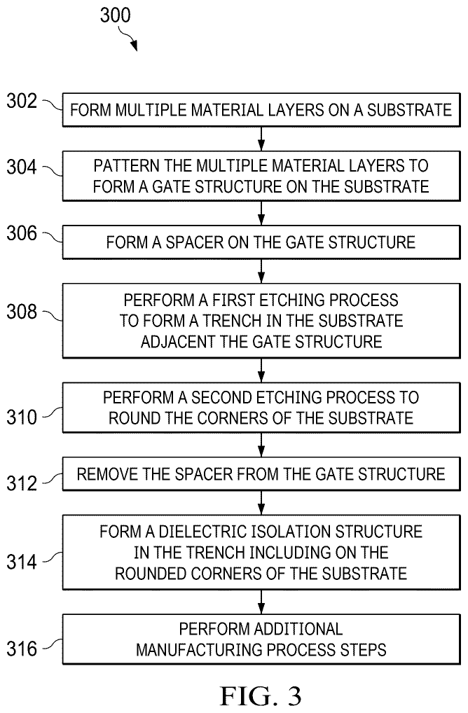

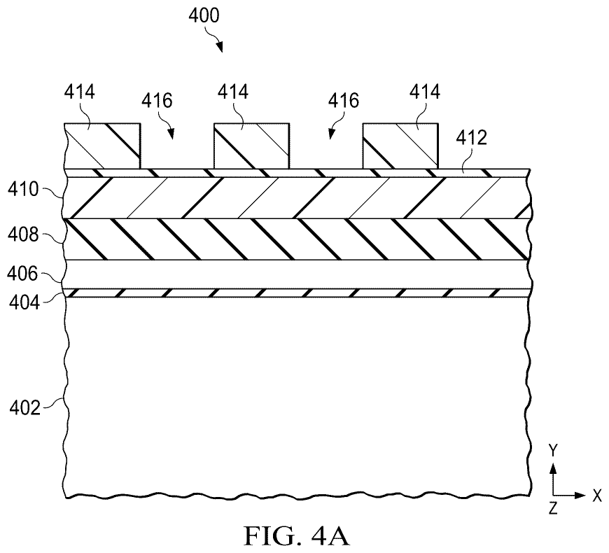

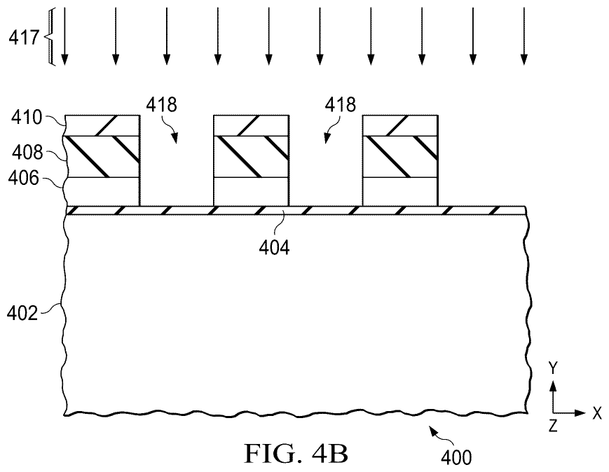

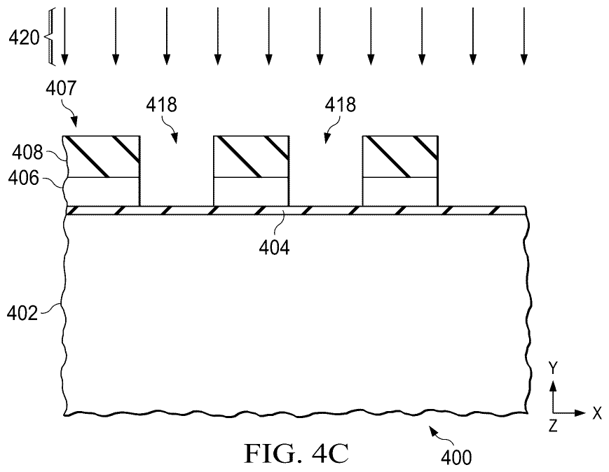

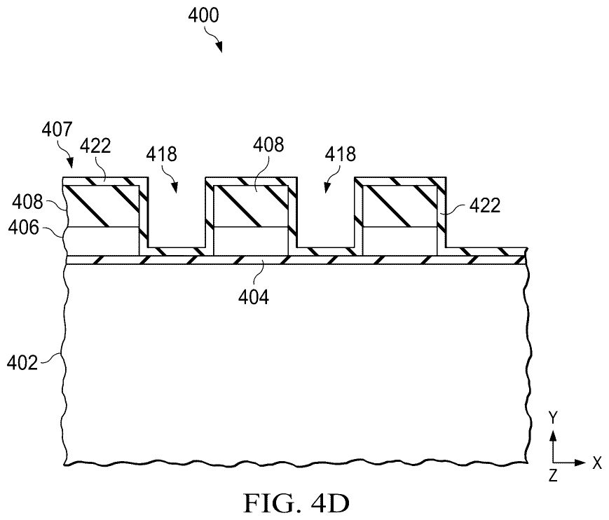

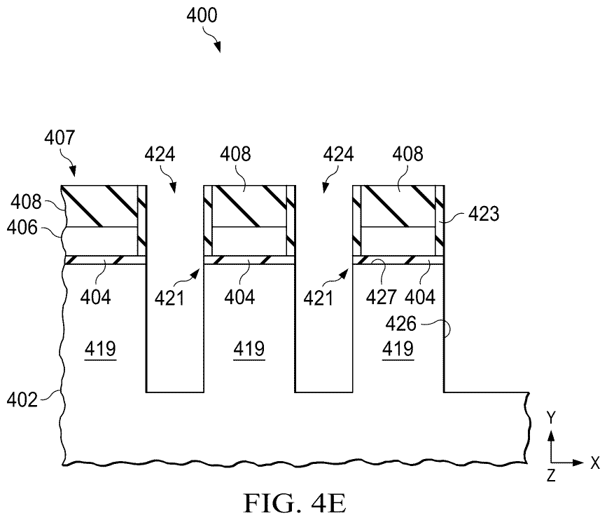

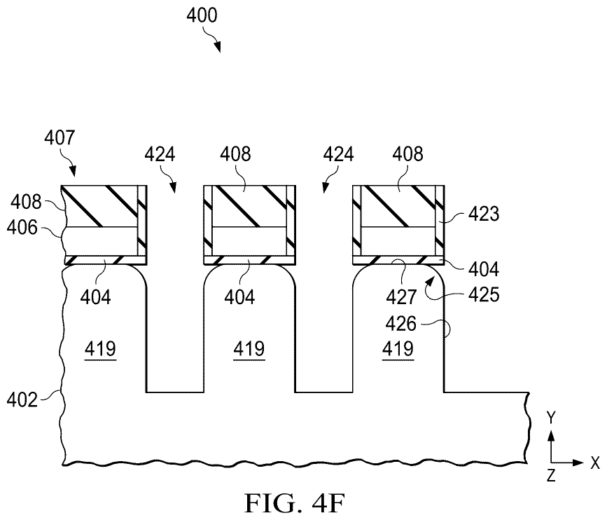

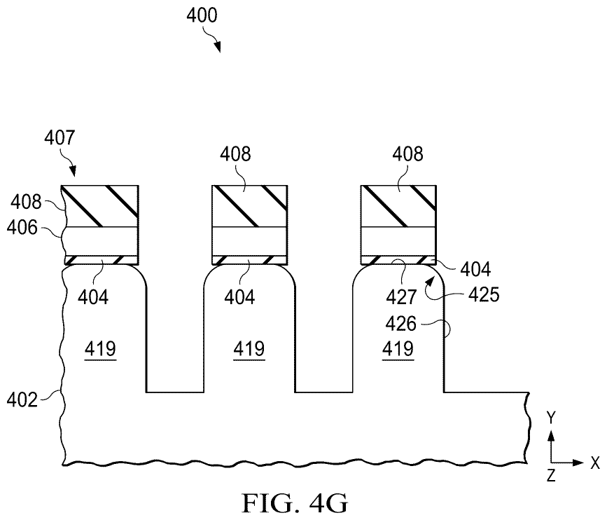

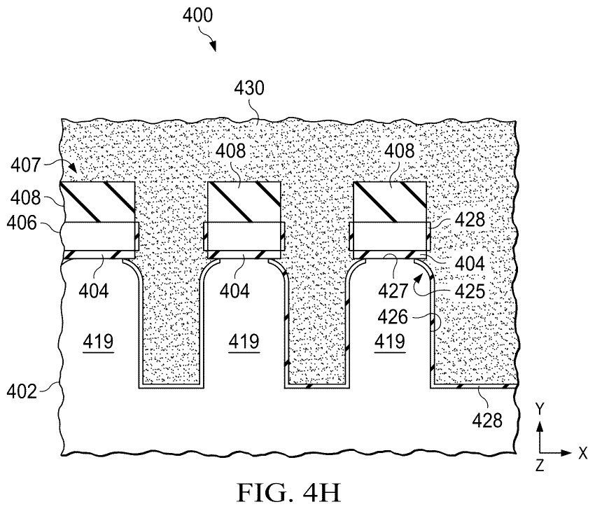

Referring now to FIG. 3, a flow diagram of a method 300 for forming a semiconductor device having an active area with sculpted corners is illustrated, in accordance with various examples of the present disclosure. In various examples, method 300 may be used to form sculpted corners in active areas of a substrate for semiconductor devices such as a field effect transistor (FET), a metal oxide semiconductor FET (MOSFET), a complimentary MOSFET (CMOS), a laterally diffused MOSFET (LDMOS), flash memory cells, among others. Additional processes can be provided before, during, and after method 300. As described below, method 300 is described with reference to FIGS. 4A-4H.

In that regard, FIGS. 4A-4H are diagrammatic cross-sectional views of a device 400 at various stages of fabrication (such as those associated with method 300 of FIG. 3), according to various aspects of the present disclosure. In various examples, device 400 may be a field effect transistor (FET), a metal oxide semiconductor FET (MOSFET), a complimentary MOSFET (CMOS), a laterally diffused MOSFET (LDMOS), flash memory cells, among others. Additional features can be added to device 400, and some features described below can be replaced, modified, or eliminated in other examples of device 400.

At step 302 of FIG. 3, multiple material layers are formed on a substrate (or a substrate is provided having one or more layers of the multiple material layers formed thereon). As shown in FIG. 4A, device 400 includes a substrate 402, a gate dielectric layer 404 (e.g., a tunnel oxide layer for flash memory cells) formed on substrate 402, a gate electrode 406 formed on gate dielectric layer 404, an inorganic hard mask 408 formed on gate electrode 406, a stop layer 410 formed on inorganic hard mask 408, and a hard mask 412 formed on stop layer 410. A patterned photoresist layer 414 is formed on hard mask 412 having openings 416. In various examples, substrate 402 may include silicon (Si) or silicon germanium (SiGe). In various examples, substrate 402 may include one or more layers of Si or SiGe. In various examples, substrate 402 may be an n-type material or a p-type material. In some examples, substrate 402 may include an insulating layer, such that substrate 402 may be considered a silicon-on-insulator (SOI) substrate.

Gate dielectric layer 404 (e.g. tunnel oxide layer) is formed on substrate 402. Gate dielectric layer 404, in various examples, may include any gate dielectric material including a high-k dielectric material. For example, gate dielectric layer 404 many include dielectric materials such as silicon oxide, hafnium oxide, and/or zirconium oxide

Gate electrode 406 is formed on gate dielectric layer 404. Gate electrode 406 may, in various examples, include polycrystalline silicon, also referred to as polysilicon, titanium nitride, and/or other metals and metal alloys. Inorganic hard mask 408 is formed on gate electrode 406. Inorganic hard mask 408 may, in various examples, include silicon oxide, silicon dioxide, silicon nitride, and/or silicon oxynitride. Stop layer 410 is formed on inorganic hard mask 408. Stop layer may be used as a sacrificial planarization stop layer. In various examples, stop layer 410 may include an optical dispersive layer (ODL), an ashable hard mask (AHM), and/or a diamond like carbon (DLC) layer.

Hard mask 412 is formed on stop layer 410. In various examples, hard mask 412 may include silicon dioxide, silicon nitride, amorphous carbon, silicon carbide, a metal oxide, or a metal alloy oxide, among others. In various examples, hard mask 412 may be a soft hard mask bi-layer (SHB) or a dielectric anti-reflective coating (DARC). Photoresist layer 414 is formed on hard mask 412. In various examples, photoresist layer 414 may include a positive photoresist material or a negative photoresist material. Openings 416 are formed through photoresist layer 414, using lithography and etch processes, to expose hard mask 412.

At step 304 of FIG. 3, the multiple material layers are patterned to form a gate structure on the substrate. As shown in FIGS. 4B and 4C, a first removal process 417 and a second removal process 420 forms a gate structure 407 (e.g. gate stack). As shown in FIG. 4B, first removal process 417 forms openings 418 through hard mask 412, stop layer 410, inorganic hard mask 408, and gate electrode 406, exposing gate dielectric layer 404 in openings 418. First removal process 417 further removes hard mask 412 and an upper portion of stop layer 410. In various examples, first removal process 417 may be a wet etch process, a dry etch process, or a combination thereof. In various examples, first removal process 417 may include one or more different etching processes.

As shown in FIG. 4C, second removal process 420 removes stop layer 410, forming gate structure 407. In various examples, second removal process 420 may include one or more different etching processes. In various examples, second removal process 420 may be a wet etch process, a dry etch process, a chemical mechanical polishing (CMP) process, or a combination thereof. As shown, after the removal of stop layer 410, gate structure 407 includes gate dielectric layer 404, gate electrode 406, and inorganic hard mask 408.

At step 306 of FIG. 3, a spacer is formed on the gate structure. As shown in FIG. 4D, a dielectric spacer layer 422 is formed on gate structure 407. In various examples, dielectric spacer layer 422 may include one or more layers of an oxide material (e.g., silicon oxide) or a nitride material (e.g., silicon nitride and/or silicon oxynitride). Dielectric spacer layer 422 may be formed using any known process, such as for example, chemical vapor deposition (CVD), and/or physical vapor deposition (PVD), among others.

At step 308 of FIG. 3, a first etching process is performed to form a trench in the substrate adjacent the gate structure. As shown in FIG. 4E, trenches 424 are formed through dielectric spacer layer 422, gate dielectric layer 404, and into substrate 402. The patterning of substrate 402 delineates portions of substrate 402 that define active areas 419. Active areas 419 are where active parts of the transistor are formed, such as a gate structure 407, a source region, and/or a drain region. As shown, corners 421 (e.g., non-sculpted or non-rounded corners) of active areas 419 of substrate 402 are at least partially exposed within trench 424. Corners 421 are defined by the intersection of sidewall 426 and top surface 427 of substrate 402. Additionally, as shown, top surface 427 of the active areas 419 is covered by gate dielectric layer 404 after trenches 424 are formed.

The non-sculpted (e.g. non-rounded) nature of corners 421 (e.g. sharp corners) tend to cause undesirable effects during use of the transistor device such as kink effect, gate dielectric breakdown, and/or other stresses that may cause junction leakage in the transistor device. To address these issues, as described below, the disclosed process sculpts (e.g. rounds) corners 421 of active areas 419 in subsequent process steps. By doing so, the undesirable effects of kink effect, gate dielectric breakdown, and/or other stresses that may cause junction leakage in the transistor are prevented and/or mitigated.

In various examples, one or more etching processes may be used to form trenches 424. In various examples, the one or more etching processes may include a dry chemical etch process, a wet chemical etch process, a reactive ion etch (RIE) process, or combinations thereof. Also, as shown in FIG. 4E, dielectric spacer layer 422 has been etched to form spacer 423. In various examples, the etching of dielectric spacer layer 422 can occur prior to performing the first etching process to form trenches 424. In such examples, spacers 423 act as a mask during the etching of gate dielectric layer 404 and substrate 402 to form trenches 424.

At step 310 of FIG. 3, a second etching process is performed to round the corners of the substrate. As shown in FIG. 4F, sculpted corners 425 (e.g. rounded corners) are formed by etching the at least partially exposed corners 421 of active areas 419 of substrate 402. More specifically, the forming of sculpted corners 425 occurs while gate structures 407 and spacers 423 are disposed over active areas 419. As shown, sculpted corners 425 transition from remaining portions of top surface 427 to remaining portions of sidewall 426 of substrate 202. In various examples, similar to the cross-sectional profiles described above with respect to the sculpted corners 224, 224′ and 224″ in FIGS. 211-2K2, sculpted corners 425 may be linear, convex, or concave, among others. As shown in FIG. 4F, sculpted corners 425 are convex corners.

One or more etching processes may form sculpted corners 425. As shown, the one or more etching processes sculpt (e.g. round) corners of active areas 419 with little to no etching of the overlying gate dielectric layer 404. As such, gate dielectric layer 404 remains interfacing (e.g. direct contact) with spacer 423 after the formation of sculpted corners 425.

In various examples, the one or more etching processes to form sculpted corners 425 may be a wet chemical etching process, a gas-phase etching process, or a combination thereof. In various examples, the one or more etching process may include a first etching process and a second etching process. In various examples, a first etching process using a fluorine-based etchant may be performed to remove native oxide and/or other oxide remnants from substrate 402, including sidewall 426. In some examples, the fluorine-based etchant may include hydrogen fluoride (HF), hydrofluoric acid, or ammonium fluoride (NH₄F) and HF. In various examples, the fluorine-based etchant may be mixed with deionized (DI) water at a ratio of about 10:1 to about 500:1. In various examples, mixing may be performed at a temperature of about 20° C. to about 55° C. Thereafter, a second etching process using ozonated deionized water (DIO₃) may be performed for oxidative etching. An ozone (O₃) concentration in the DIO₃, in various examples, may be about 1 ppm to about 100 ppm. In various examples, the DIO₃ may be used at a temperature of about 20° C. to about 40° C. The second etching process using DIO₃ may asymmetrically etch sidewall 426 of substrate 402. In various examples, the wet chemical etching process may etch, or remove, substrate 402 asymmetrically from an upper portion (e.g., in the positive y-direction) to a lower portion (e.g., in the negative y-direction). In other words, the asymmetric etch may remove more material from substrate 402 at the upper portion than at the lower portion to form sculpted corners 425. The asymmetric etch may be a result of a concentration gradient and decay of the dissolved DIO₃ that is used—e.g., as the strength of the oxidative etching decreases toward the lower portion of the trenches 424. In various examples, a vertical depth of the etch may be controlled by altering the process, or exposure, times of the wet chemical etch process. In various examples, the second etching process including the DIO₃ may be performed before the first etching process including the fluorine-based etchant. The first etching process and the second etching process may be repeated one or more times depending on a target critical dimension bias.

In various alternative examples, the one or more etching processes to form sculpted corners 425 may include a vapor etch process, also referred to as gas-phase chemical etch or a chemical dry etch. In these various alternative examples, the vapor etch process may have a high selectivity of Si over an oxide material and/or nitride material. For example, when substrate 402 is formed of silicon and gate dielectric layer 404 is formed of an oxide material (e.g. silicon oxide and/or silicon oxynitride), and spacer 423 is formed of a nitride material (e.g. silicon nitride and/or silicon oxynitride), the vapor etch process may etch more of substrate 402 than either of gate dielectric layer 404 or spacer 423 due to the high etch selectivity for silicon. As such, corners 421 of the active areas 419 are rounded to form sculpted corners 425. The etching process may be modified to affect the degree to which corners 421 of active areas 419 are sculpted (e.g. rounded). For example, the etch may be tuned by modifying the etchant used, the concentration of the etchant, the temperature of the chamber used, the pressure of the chamber, and/or the duration of the etch, among others.

In various examples, the vapor etch process may be an isotropic vapor etch process. The vapor etch process may include nitrogen trifluoride (NF₃), ammonia (NH₃), hydrofluorocarbons (CₓH_{y}Fₓ), sulfur hexafluoride (SF₆), boron trifluoride (BF₃), or other fluorine-based etchants. In various examples, one or more carrier gases may be used during the vapor etch process. For example, the one or more carrier gases may be one or more noble gases including argon (Ar), helium (He), neon (Ne), and/or nitrogen (N₂), among others. In various examples, the high etch selectivity provides precise control for removal of substrate 402 (e.g. silicon substrate) with a gradient etch profile from top to bottom tunability—e.g., removing mores Si near the top surface of the substrate than near the bottom of the trench. The etch may be tuned by modifying the etchant used, the concentration of the etchant, the temperature of the chamber used, the pressure of the chamber, and/or the duration of the etch, among others. In various examples, the vapor etch process may be performed at a pressure of about 0.001 Torr to about 10 Torr. In various examples, the etchants may be about 10% to about 100% relative to the one or more carrier gases used. In various examples, the temperature of the vapor etch process may be about 10° C. to about 250° C.

It is understood that using the disclosed process that sculpted corners 425 of active areas 419 may have different profiles other than the shown convex profile. For example, sculpted corners 425 may be etched to have linear and/or concave profiles such as those described above with respect to FIGS. 2J1, 2J2, 2K1 and 2K2. As described above, the different cross-sectional profiles of sculpted corners 425 may be achieved by adjusting the parameters of the etching processes described above. In various examples, the adjusted parameters may include a type of etchant, a concentration of the etchant, a temperature of the etching process, a timing of the etching process and/or the pressure of the etching process, among other parameters.

At step 312 of FIG. 3, the spacer is removed from the gate structure. As shown in FIG. 4G, spacers 423 are removed from sidewalls of the various gate structures 407. One or more etching process may be used to remove spacers 423. In various examples, the one or more etching processes may include a dry chemical etch process, a wet chemical etch process, an anisotropic etch such as a reactive ion etch (RIE) process, or combinations thereof. As shown, after the removal of spacer 423, sidewalls of gate electrode 406, inorganic hard mask 408 and tunnel oxide layer are exposed. Additionally, a portion of gate dielectric layer 404 that was directly under spacer 423 is also removed during the removal process of spacer 423.

At step 314 of FIG. 3, a dielectric isolation structure is formed in the trench including on the rounded corners of the substrate. As shown in FIG. 4H, a dielectric liner 428 and a dielectric material 430 are formed on device 400 including in trenches 424 to form a dielectric isolation structure. Dielectric liner 428 may be formed on sidewall 426 and sculpted corners 425 of active area 419 and on gate electrode 406. In particular, dielectric liner 428 may conform to the sculpted corners 425 such that the sculpted nature (e.g. roundness) of the corner is continued in the cross-sectional profile of the dielectric liner 428. In some examples, forming dielectric liner 428 may further round the sculpted corners 425. In various examples, dielectric liner 428 may be formed using a thermal oxidation process, a diffusion process, a chemical vapor deposition (CVD) process, or a physical vapor deposition (VPD) process. In various examples, dielectric liner 428 may be grown on substrate 402 and gate electrode 406. In various examples, dielectric liner 428 may include silicon oxide, silicon dioxide, silicon nitride, silicon oxynitride, or combinations thereof.

Dielectric material 430 may be formed on dielectric liner 428, gate dielectric layer 404, and inorganic hard mask 408. In various examples, dielectric liner 428 may include silicon oxide, silicon dioxide, silicon nitride, silicon oxynitride, or combinations thereof. In various examples, a planarization process may be performed on dielectric material 430 to form the dielectric isolation structure. In various examples, dielectric liner 428 and dielectric material 430 may have different material compositions. In various examples, dielectric liner 428 and dielectric material 430 may have similar material compositions.

At step 316 of FIG. 3, additional manufacturing process steps may be performed. Additional manufacturing steps may include forming source regions, drain regions, and/or body regions. Additional manufacturing steps may further include forming source contacts, drain contacts, and/or gate contacts.

As described above, transistors disposed on active areas having non-sculpted corners (e.g. sharp corners) may have undesirable effects during use of the transistor devices including kink effect, gate dielectric breakdown, and/or other stresses that may cause junction leakage in the transistor device. To address these issues, disclosed herein are methods for manufacturing semiconductor devices having active areas with sculpted corners. A transistor, such as a field effect transistor (FET), disposed over such an active area having sculpted corners tends to reduce otherwise the undesirable effects associated active areas not having sculpted corners.

Specifically, for example, sculpted corners 425 of active areas 419 provide improvements to field effect transistors, structurally and electrically. Structurally, sculpted corners 425 tend to mitigate, in various examples, the stress that may lead to gate dielectric breakdown and/or junction leakage. For example, sculpted corners 425 mitigate these effects by reducing the sharpness of the corners (e.g. non-sculpted corner 421) of active areas 419. The reduced sharpness of sculpted corners 425 tend to reduce structural stress that may lead to gate dielectric breakdown and/or junction leakage. Electrically, sculpted corners 425 also provide additional space for dielectric material (e.g. dielectric liner 428 and/or dielectric material 430) which in turns provides more isolation of active areas 419 from gate structure 407 and/or source/drain regions. Sculpted corners 425 further tend to reduce unwanted accumulation of electric charge at, or near, the sculpted corners of active areas in the FETs. In other words, FETs that have sharp corners and/or edges (e.g. non-sculpted corners such as corner 421) in active areas tend to have unwanted accumulation of electric charge near these non-rounded corners. Reducing the unwanted accumulation of electric charge through devices having active areas with sculpted corners 425 tends to reduce parasitic current leakage and/or capacitances.

Accordingly, the methods disclosed herein provide a way to sculpt the corners of active areas in a substrate material using fewer steps and at less expense than other techniques. Using the methods described herein, sculpted corners may be formed on substrate, including in active areas, either before forming the gate structure or after forming the gate structure. The etching processes disclosed herein provide control to sculpt active area corners to have a convex profile, a concave profile, a linear profile, or other profiles. Having sculpted corners for active areas advantageously improves the structural and electrical properties of a transistor disposed thereon by preventing or mitigating the undesirable effects of kink effect, gate dielectric breakdown, and/or other stresses that may cause junction leakage in the transistor.

Finally, it should be understood that any of the above-described concepts can be used alone or in combination with any or all of the other above-described concepts. Although various examples have been disclosed and described, it is understood, recognized, and/or contemplated that certain modifications would come within the scope of this disclosure. Accordingly, the description is not intended to be exhaustive or to limit the principles described or illustrated herein to any precise form. Many modifications and variations are possible in light of the above teaching.

What is claimed is:

1. A method, comprising:
forming a gradient oxide layer on a surface of a substrate, wherein an etch rate of the gradient oxide layer varies along a thickness of the gradient oxide layer;
forming a trench through the gradient oxide layer and into the substrate, the trench at least partially defined by a sidewall of the substrate, wherein the surface and the sidewall are connected to form a corner of the substrate;
removing a portion of the gradient oxide layer adjacent the corner, wherein a portion of the surface of the substrate is exposed as a result of removing the portion of the gradient oxide layer;
performing an etching process on the exposed corner of the substrate to form a rounded corner that transitions from the surface of the substrate to the sidewall of the substrate; and
forming a dielectric layer on the rounded corner of the substrate.

2. The method of claim 1, wherein forming the dielectric layer on the rounded corner further rounds the rounded corner.

3. The method of claim 1, further comprising:
forming a dielectric isolation structure on the dielectric layer, the dielectric isolation structure filling the trench.

4. The method of claim 1, wherein the gradient oxide layer includes a concentration of oxygen that varies along the thickness of the gradient oxide layer such that the concentration of oxygen increases within the gradient oxide layer in a direction toward the substrate.

5. The method of claim 1, wherein the etch rate of the gradient oxide layer is greater at a lower portion of the gradient oxide layer adjacent the substrate than an opposing upper portion of the gradient oxide layer.

6. The method of claim 1, wherein the gradient oxide layer includes a plurality of oxide layers, the plurality of oxide layers including a first oxide layer that is adjacent the substrate, the first oxide layer having a greater etch rate than other oxide layers from the plurality of oxide layers.

7. The method of claim 1, wherein the gradient oxide layer has a sidewall surface exposed to the trench, the sidewall surface having a retrograde profile as a result of removing the portion of the gradient oxide layer.

8. The method of claim 1, wherein the etching process is a wet etching process that includes using an ozonated deionized water.

9. The method of claim 8, wherein the etching process further includes removing oxide from the corner of the substrate prior to using the ozonated deionized water.

10. The method of claim 1, wherein the etching process includes using a fluorine-based etchant.

11. The method of claim 1, wherein the rounded corner of the substrate has a convex profile after the performing of the etching process.

12. The method of claim 1, wherein the rounded corner of the substrate has a concave profile after the performing of the etching process.

13. A method, comprising:
forming a gate stack on a surface of a substrate, the gate stack including a gate dielectric layer and a gate electrode layer;
forming a dielectric spacer on the gate stack;
forming a trench in the substrate adjacent the dielectric spacer, the trench at least partially defined by a sidewall of the substrate;
removing, through the trench, a portion of the substrate from under the dielectric spacer to form a rounded corner on the substrate, the rounded corner transitioning from the surface of the substrate to the sidewall of the substrate; and
forming a dielectric layer on the rounded corner of the substrate.

14. The method of claim 13, wherein forming the dielectric layer on the rounded corner further rounds the rounded corner.

15. The method of claim 13, further comprising:
forming a dielectric isolation structure on the dielectric layer, the dielectric isolation structure filling the trench.

16. The method of claim 15, further comprising:
removing the dielectric spacer prior to forming the dielectric isolation structure in the trench.

17. The method of claim 13, wherein removing the portion of the substrate from under the dielectric spacer includes performing a wet etching process using an ozonated deionized water.

18. The method of claim 13, wherein removing the portion of the substrate from under the dielectric spacer includes performing an etching process using a fluorine-based etchant.

19. The method of claim 13, wherein forming the dielectric layer on the rounded corner of the substrate also forms the dielectric layer on the gate electrode layer.

20. The method of claim 13, wherein the gate electrode layer includes a polysilicon material.

21. A method, comprising:
forming an oxide layer on a surface of a semiconductor substrate;
forming a trench through the oxide layer and into the semiconductor substrate, the trench at least partially defined by a sidewall of the semiconductor substrate;
performing an etching process on the semiconductor substrate including the sidewall to form a rounded corner on the semiconductor substrate, wherein the rounded corner transitions from the sidewall of the semiconductor substrate to the surface of the semiconductor substrate that is covered by the oxide layer, wherein the etching process includes using an ozonated deionized water or a fluorine-based etchant; and
forming a dielectric layer on the rounded corner of the semiconductor substrate.

22. The method of claim 21, wherein forming the dielectric layer on the rounded corner further rounds the rounded corner.

23. The method of claim 21, wherein the etching process is a wet etching process using the ozonated deionized water to form the rounded corner of the semiconductor substrate, and
wherein performing the etching process further includes using a fluorine-based gas before using the ozonated deionized water.

24. The method of claim 21, wherein an etch rate of the oxide layer is greater at a lower portion of the oxide layer adjacent the surface of the semiconductor substrate than an opposing upper portion of the oxide layer.
